(19) United States
(12) Patent Application Publication
(10) Pub. No.: US 2016/0094692 A1
(43) Pub. Date: Mar. 31, 2016

(54) MOBILE PHONES WITH HEAT DISSIPATION COMPONENTS, MANUFACTURING METHOD AND HEAT DISSIPATION DEVICE THEREFOR

(71) Applicant: MediaTek Singapore Pte. Ltd., Singapore (SG)

(72) Inventor: Wei ZHANG, Shenzhen City (CN)

(21) Appl. No.: 14/870,521

(22) Filed: Sep. 30, 2015

(30) Foreign Application Priority Data
Sep. 30, 2014 (CN) 201410526209.1

(51) Int. Cl. H04M 1/02; H05K 7/20; B23P 15/26

(52) U.S. Cl. CPC H04M 1/026; B23P 15/26; H05K 7/2039

(57) ABSTRACT

A mobile phone is provided. A heating component has a heating surface. A heat dissipation component has a heat absorbing surface. A thermal phase-change material layer is thermally connected between the heating surface and the heat absorbing surface and has a phase-change temperature. The thermal phase-change material layer is manufactured by silk screen printing, and space between the heat absorbing surface and the heating surface is less than or equal 0.1 mm. A manufacture method for the mobile phone is provided. By the method, when a temperature of the heating component reaches or exceeds the phase-change temperature, the thermal phase-change material layer is changed to a melting phase from a solid phase and fills the space between the heating component and the heat dissipation component. So as to conduct the heat of the heating component to the heat dissipation component, thus improving the heat dissipation performance of the mobile phone.

### CROSS REFERENCE TO RELATED APPLICATIONS

This Application claims priority of China Patent Application No. 201410526209.1, filed on Sep. 30, 2014, the entirety of which is incorporated herein by reference.

### BACKGROUND OF THE INVENTION

1. Field of the Invention

The invention relates to communication technique, and, more particularly, to a manufacturing method for mobile phones and a mobile phone using the manufacturing method.

2. Description of the Related Art

With the improvement of living quality, mobile phones are widely used in daily life. Almost everyone has a mobile phone. Mobile phones are provided to make calls, but are also provided with a variety of entertaining features, such as watching movies, playing games, or listening to music. However, watching movies, playing games, or listening to music by mobile phones consumes much power. After a long time of use, the temperature of mobile phones may rise significantly.

Heat dissipation of mobile phones is a problem major mobile phone manufacturers seek to solve. However, there is no breakthrough yet. Almost all the mobile phones place heat dissipation components on heating components for dissipating the heat. For example, within a mobile phone, a heat dissipator is disposed or thermal silica gel is placed on a heating component. The heat dissipator and the conductive silica gel are capable of dissipating heat to a certain level, however, the effect of heat dissipation is not satisfying, so that the overall performance of the heat dissipation for the mobile phone is downgraded.

### BRIEF SUMMARY OF THE INVENTION

Thus, it is desirable to provide a manufacturing method for mobile phones and a mobile phone using the manufacturing method, thereby enhancing performance of heat dissipation for mobile phones.

An exemplary embodiment of a mobile phone is provided. The mobile phone comprises a heating component, a heat dissipation component, and a thermal phase-change material layer. The heating component has a heating surface. The heat dissipation component has a heat absorbing surface. The thermal phase-change material layer is thermally connected between the heating surface of the heating component and the heat absorbing surface of the heat dissipation component and has a phase-change temperature. When a temperature of the heating component reaches or exceeds the phase-change temperature, the thermal phase-change material layer is changed to a melting phase from a solid phase. The thermal phase-change material layer is manufactured by silk screen printing, and space between the heat absorbing surface and the heating surface is less than or equal 0.1 mm.

In one embodiment, a thickness of the thermal phase-change material layer is configured to maintain a shape of the thermal phase-change material layer at the melting phase to be the same as the shape of the thermal phase-change material layer at the solid phase through surface adsobability and tension of the thermal phase-change material layer.

In another embodiment, a thickness of the thermal phase-change material layer is less than or equal to 0.1 mm.

In further another embodiment, an area of the thermal phase-change material layer is equal to an area of the heating surface of the heating component.

In another embodiment, an area of the thermal phase-change material layer is larger than or equal to 15 mm×15 mm.

In further another embodiment, the heating component is a PCB component, a camera disposed inside the mobile phone, or a liquid crystal display screen disposed inside the mobile phone, and the heat dissipation component is a metallic sheathing

In one embodiment, the thermal phase-change material layer has a grid structure or polygon structure.

In another embodiment, the phase-change temperature is in a range of 40° C.-60° C.

An exemplary embodiment of a manufacturing method for a mobile phone is provided. The manufacture method comprises steps of providing a heating component having a heating surface and a heat dissipation component having a heat absorbing surface; forming a thermal phase-change material layer on at least one of the heating component and the heat dissipation component through silk screen printing; pressing the heating component and the heat dissipation component to each other, so that the thermal phase-change material layer is thermally connected between the heating surface of the heating component and the heat absorbing surface of the heat dissipation component. The thermal phase-change material layer has a phase-change temperature. When a temperature of the heating component reaches or exceeds the phase-change temperature, the thermal phase-change material layer is changed to a melting phase from a solid phase. After the heating component and the heat dissipation component are pressed to each other, space between the heat absorbing surface and the heating surface is less than or equal 0.1 mm.

In one embodiment, a thickness of the thermal phase-change material layer is configured to maintain a shape of the thermal phase-change material layer at the melting phase to be the same as the shape of the thermal phase-change material layer at the solid phase through surface adsobability and tension of the thermal phase-change material layer.

In another embodiment, a thickness of the thermal phase-change material layer is less than or equal to 0.1 mm.

In further embodiment, an area of the thermal phase-change material layer is equal to an area of the heating surface of the heating component.

In another embodiment, an area of the thermal phase-change material layer is larger than or equal to 15 mm×15 mm.

In further another embodiment, the heating component is a PCB component, a camera disposed inside the mobile phone, or a liquid crystal display screen disposed inside the mobile phone, and the heat dissipation component is a metallic sheathing

In one embodiment, the thermal phase-change material layer has a grid structure or polygon structure.

In another embodiment, the phase-change temperature is in a range of 40° C.-60° C.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 shows an exemplary embodiment of a structure of a mobile phone;

FIG. 2 shows a curve of heat-dissipation effect of a mobile phone when various media are adopted according to an exemplary embodiment; and

FIG. 3 shows a flow chart of a manufacturing method for mobile phones according to an exemplary embodiment.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

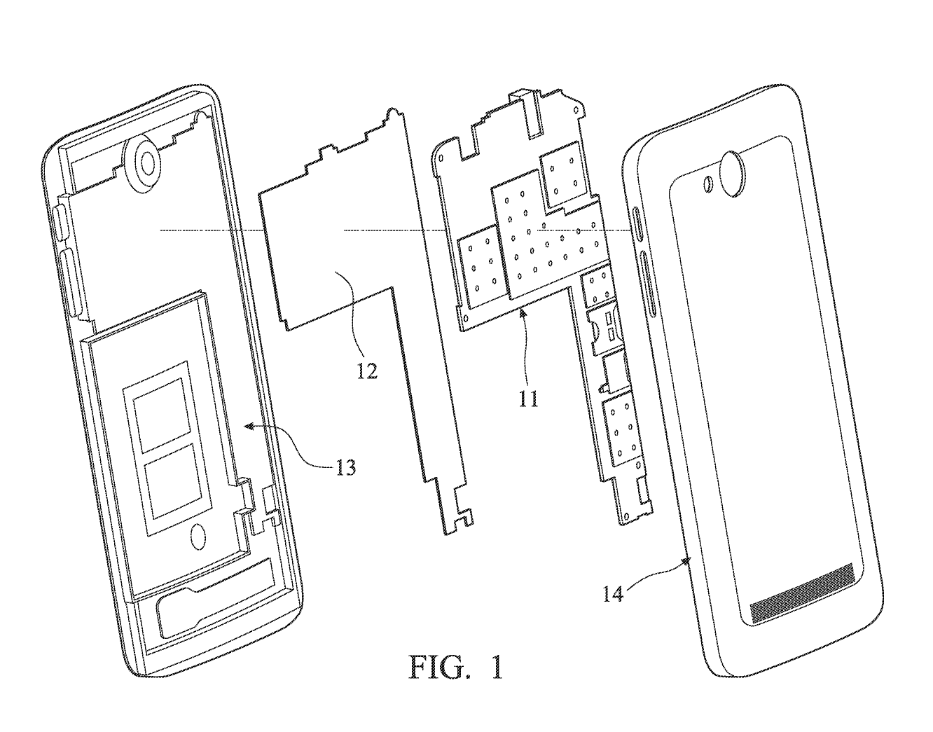

FIG. 1 shows an exemplary embodiment of a structure of a mobile phone. The mobile phone 1 comprises a heating component 11 having a heating surface, a heat dissipation component 13 having a heat absorbing surface, a thermal phase-change material layer 12, and a case 14. The dissipation component 13 and the thermal phase-change material layer 12 are disposed on the case 14. The thermal phase-change material layer 12 is thermally connected between the heating surface of the heating component 11 and the heat absorbing surface of the heat dissipation component 13. In this embodiment, the heating component 11 is a PCB component, a camera disposed inside the mobile phone, or a liquid crystal display screen disposed inside the mobile phone. The heat dissipation component 13 is a metallic sheathing. The PCB component is implemented by at least one of a PCB board, a surface mount resistor disposed on a PCB board, a surface mount capacitor disposed on a PCB board, a power element disposed on a PCB board, a mobile phone chip disposed on a PCB board, and other heating components disposed on a PCB board. The metallic sheathing is a metallic frame inside the mobile phone. For example, the metallic sheathing is a metallic shell surface disposed at the center of the frame of the mobile phone, a metallic shell surface disposed at the bottom of the mobile phone, or a metallic shell disposed at the periphery of the frame of the mobile phone. In other embodiments, the heating component 11 is not limited to a PCB component, a camera disposed inside the mobile phone, or a liquid crystal display screen disposed inside the mobile phone. The heating component 11 may be other heating elements, such as a touch panel or speaker. The metallic shell is not limited to the metallic frame inside the mobile phone. In other embodiments, the metallic shell can be a heat dissipation metallic object disposed inside the mobile phone.

The area of the thermal phase-change material layer 12 is equal to the area of the heating surface of the heating component 11 to ensure the well contact on the contact face. In other words, no matter what shapes of the heating surface of the heating component 11 is (a regular shape or irregular shape), the area of the thermal phase-change material layer 12 is equal to the area of the heating surface of the heating component 11. Alternatively, the area of the thermal phase-change material layer 12 is slightly larger or smaller than the area of the heating surface of the heating component 11. If the shape of the thermal phase-change material layer 12 is a regular square shape, the shape of the heating surface of the heating component 11 is also a regular square shape. If the shape of the thermal phase-change material layer 12 is an irregular shape “Y”, the shape of the heating surface of the heating component 11 is also an irregular shape “Y”. In an embodiment, the area of the thermal phase-change material layer 12 is equal to the area of the heat absorbing surface of the heat dissipation component 13, or the area of the thermal phase-change material layer 12 is slightly larger or smaller than the area of the heat absorbing surface of the heat dissipation component 13.

It would be understood that the area of the thermal phase-change material layer 12 is determined according to specific design requirements. For example, in general, when the thermal phase-change material layer 12 is applied for a mobile phone chip (heating component 11) on the front of the PCB circuit board, the area of the thermal phase-change material layer 12 is slightly smaller than the area of the mobile phone chip (heating component 11). When the thermal phase-change material layer 12 is applied for the corresponding heating region on the back of the PCB circuit board, the area of the thermal phase-change material layer 12 is slightly larger than the area of the corresponding heating region on the back of the PCB circuit board. In brief, the thermal phase-change material layer 12 is designed to ensure the effective thermal conduction between the heating component 11 and the heat dissipation component 13.

In the mobile phone, the space between the heat absorbing surface of the heat dissipation component 13 and the heating surface of the heating component 11 is less than or equal to 0.1 mm. Accordingly, the thickness of the thermal phase-change material layer 12 is designed to be less than or equal to 0.1 mm. In this embodiment, the thermal phase-change material layer 12 has low hardness and better compressibility. Therefore, by pressing the heat dissipation component 13 and the heating component 11 to each other, the thermal phase-change material layer 12 is thermally connected between the heating surface of the heating component 11 and the heat absorbing surface of the heat dissipation component 13, such that the thickness of the thermal phase-change material layer 12 is less than or equal to 0.1 mm. In another embodiment, after the heating component 11 and the heat dissipation component 13 are pressed to each other, the thickness of the thermal phase-change material layer 12 is less than or equal to 0.08 mm. Further, the area of the thermal phase-change material layer 12 is larger than or equal to 15 mm×15 mm. It would be understood that the area of the thermal phase-change material layer 12 is larger than or equal to 255 mm². Thus, no matter what shape of the thermal phase-change material layer 12 is, the area of the thermal phase-change material layer 12 should be larger than or equal to 255 mm².

The thermal phase-change material layer 12 may be formed by using one thermal material layer or by using a plurality of thermal material layers jointly. In an embodiment, the entire area of the thermal phase-change material layer 12 is larger or equal to 15 mm×15 mm. In another embodiment, the thermal phase-change material layer 12 is formed by piecing three thermal material layers, wherein each of them is equal to 10 mm×10 mm. In further another embodiment, the thermal phase-change material layer 12 is formed by piecing one thermal material layer whose area is 15 mm×15 mm and one thermal material layer whose area is 6 mm×6 mm. The thermal phase-change material layer 12 has a grid structure or polygon structure. Via the above specific structures, overflow conditions is reduced, and the thermal phase-change material layer 12 with larger area and less thickness is obtained. In another embodiment, the thermal phase-change material layer 12 is a block type or a large plane type. It would be understood that the structure of the thermal phase-change material layer 12 is designed in response to specific requirements, it could be any form. For a conventional thermal component, such as a thermal silica gel sheet, the minimum thickness of the thermal silica gel sheet is 0.2 mm, and the maximum area of which is 12 mm×12 mm. Thus, the conventional thermal silica gel sheet cannot achieve a thickness which is less than or equal to 0.2 mm and an area which is larger than or equal to 12 mm×12 mm. The thermal phase-change material layer 12 according to embodiments of the invention can achieve a thickness which is equal or thinner than 0.1 mm and an area which is equal or lager than 15 mm×15 mm. It is easier to realize ultra-thin design for mobile phones by applying the thermal phase-change material layer 12 of the embodiment.

The thermal phase-change material layer 12 is manufactured by silk-screen printing. In detail, the thermal phase-change material layer 12 is formed on at least one of the heat dissipation component 13 and the heating component 11 by the silk-screen printing. In a normal condition, a thermal phase-change material is at a viscous phase and stored in a sealed pot at a temperature being under 27° C. Before using the thermal phase-change material, effective stir process must be required to ensure that the thermal phase-change material can be mixed with the solvent congruently, such that the thermal phase-change material becomes to be in a viscous phase. Thus, the thermal phase-change material at the viscous phase can be printed on a silk-screen printer (not shown) to manufacture thermal phase-change material layer 12 with the thickness of 0.02-0.3 mm. During the manufacture of the thermal phase-change material layer 12, the thermal phase-change material layer 12 is formed by designating corresponding opening region on the screen of the silk-screen printer according to the shape or area of the heating component 11 or the heat dissipation component 13, and adjusting the thickness of the screen.

The thermal phase-change material layer 12 has a phase-change temperature which is in the range of 40° C.-60° C. When the temperature of the heating component 11 reaches or exceeds the phase-change temperature, the thermal phase-change material layer 12 is changed to a melting viscous phase from a solid phase and then fills the space between the heating component 11 and the heat dissipation component 13 to ensure the well contact between the thermal phase-change material layer 12, the heating component 11, and the heat dissipation component 13. Thus, the heat can be effectively conducted from the heating component 11 to the heat dissipation component 13 through the thermal phase-change material layer 12. On the contrary, a conventional thermal component, such as a thermal silica gel sheet or copper sheet, continuously keeps its shape unchanged no matter what temperature of the heating component 11 is. The thermal silica gel sheet or copper sheet cannot fully contact with the heating component 11 and the heat dissipation component 13 in the space between the heating component 11 and the heat dissipation component 13, resulting a worse effect of heat conduction.

In this embodiment, the thickness of the thermal phase-change material layer 12 is determined to keep the shape of the thermal phase-change material layer 12 at the melting phase to be the same as the shape thereof at the solid phase through the surface adsobability and tension of the thermal phase-change material layer 12. That is, when the temperature of the heating component 11 reaches the phase-change temperature in the range 40° C.-60° C., the thermal phase-change material layer 12 is changed to the melting phase from the solid phase and then fills the space between the heating component 11 and the heat dissipation component 13. Since the thermal phase-change material layer 12 has grid structure, polygon structure, or a shape with a large area formed by the silk-screen printing, the shape of the thermal phase-change material layer 12 at the melting phase is kept as the same shape thereof at the solid phase through the surface adsobability and tension of the thermal phase-change material layer 12. When the temperature of the heating component 11 is lower than the phase-change temperature, the thermal phase-change material layer 12 is automatically changed to the original shape.

The cost of the thermal phase-change material layer 12 recited in the embodiment is lower. For example, in the TIF series, the size of one thermal material TIF520S is 0.5×12×12 mmT and the price thereof is 0.026 US dollars per piece; the size of one thermal material TIF620 is 0.5×12×12 mmT and the price thereof is 0.037 US dollars per piece; the size of one thermal material TIF820 is 0.5×12×12 mmT and the price thereof is 0.026 US dollars per piece; the size of one thermal material TIF620G is 0.5×12×12 mmT and the price thereof is 0.039 US dollars per piece. For phase-change materials, the size of one phase-change material TIC808A is 0.2×12×12 mmT and the price thereof is 0.013 US dollars per piece. Compared with conventional thermal materials, copper materials, or graphite sheets, the cost of the thermal phase-change material is advantageously lower. For example, the price of the thermal phase-change material is lower than half of the price of the conventional thermal materials.

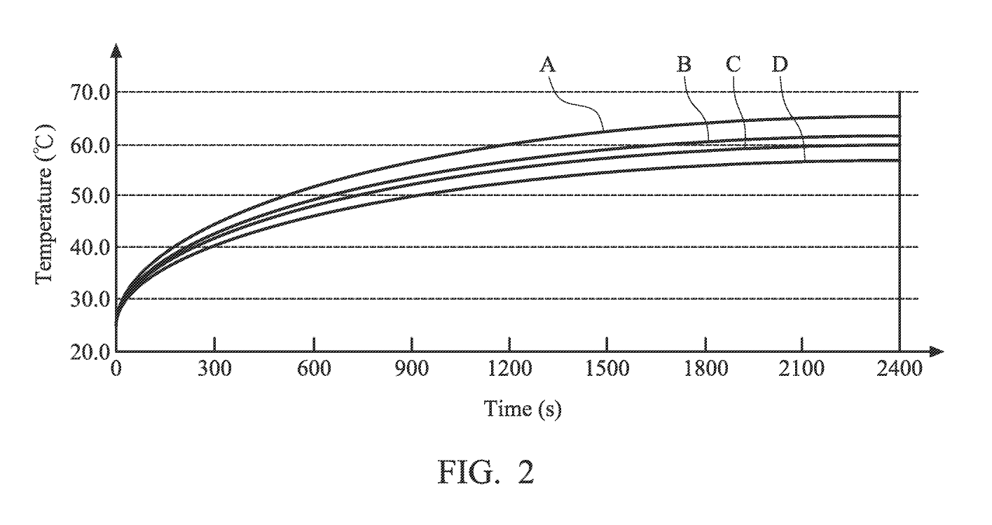

According to the embodiment, the effect of the heat conduction of the thermal phase-change material layer 12 is enhanced. FIG. 2 shows a curve of heat-dissipation effect of a mobile phone chip in different media according to an exemplary embodiment. In the embodiment, a mobile phone chip is given as an example for the heating component 11. In FIG. 2, the X-axis represents the time, the Y-axis represents the temperature, the label “A” represents the temperature curve when there is no medium disposed on between the mobile phone chip and the heat dissipation component 13, the label “B” represents the temperature curve when a first medium (such as a thermal silica gel sheet) is disposed between the mobile phone chip and the heat dissipation component 13, the label “C” represents the temperature curve when a second medium (such as a copper sheet or another thermal sheet) is disposed between the mobile phone chip and the heat dissipation component 13, and the label “D” represents the temperature curve when the thermal phase-change material layer 12 is disposed between the mobile phone chip and the heat dissipation component 13. In the embodiment of FIG. 2, the environment temperature is 24.2° C., and the thickness of the thermal phase-change material layer 12 is 0.05 mm.

TABLE 1

| | Temperature |
|---|---|
| Heating component | value/° C. |
| First temperature of the mobile phone chip (A) | 65.5 |
| Second temperature of the mobile phone chip (B) | 60.8 |
| Third temperature of the mobile phone chip (C) | 60.5 |
| Fourth temperature of the mobile phone chip (D) | 57.2 |

As shown in Table 1, the temperature is detected when the heating time of the mobile phone chip reaches 2400s. The first temperature of the mobile phone chip is 65.5° C., the second temperature of the mobile phone chip is 60.8° C., the third temperature of the mobile phone chip is 60.5° C., and the fourth temperature of the mobile phone chip is 57.2° C. According to the above, the thermal ratio of the thermal phase-change material layer 12 is better. As the thermal phase-change material layer 12 is disposed between the mobile phone chip and the heat dissipation component 13 to serve as a thermal medium, the performance of the heat dissipation is enhanced.

In the embodiment, the thermal phase-change material layer 12 has low hardness and better compressibility. Then, the heating surface of the heating component 11 and the heat absorbing surface of the heat dissipation component 13 is thermally connected by the thermal phase-change material layer 12 through pressing manner, the well contact between the heating surface of the heating component 11 and the heat absorbing surface of the heat dissipation component 13 can be maintained, thereby enhancing performance of the heat dissipation. Moreover, since the thickness of the thermal phase-change material layer 12 is less than or equal to 0.1 mm, the ultra-thin design for mobile phones may be realized easily.

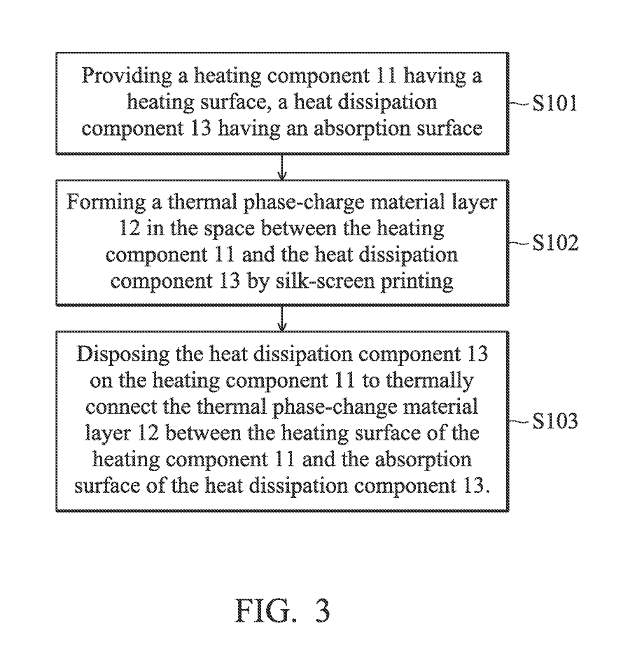

FIG. 3 is a flow chart of a manufacturing method for a mobile phone according to an exemplary embodiment. The manufacturing method comprises the following steps:

Step S101: providing a heating component 11 having a heating surface and a heat dissipation component 13 having a heat absorbing surface.

In the embodiment, the heating component 11 is a PCB component, a camera disposed or a liquid crystal display screen inside the mobile phone. The heat dissipation component 13 is a metallic sheathing. The PCB component is implemented by at least one of a PCB board, a surface mount resistor disposed on a PCB board, a surface mount capacitor disposed on a PCB board, a power element disposed on a PCB board, a mobile phone chip disposed on a PCB board, and other heating components disposed on a PCB board. The metallic sheathing is a metallic frame disposed inside mobile phone. For example, the metallic sheathing is a metallic shell surface disposed at the center of the frame of the mobile phone, a metallic shell surface disposed at the bottom of the mobile phone, or a metallic shell disposed at the periphery of the frame of the mobile phone.

Step S102: forming a thermal phase-change material layer 12 on at least one of the heat dissipation component 13 and the heating component 11 by silk-screen printing.

In Step S102, the thermal phase-change material layer 12 is formed on the heat dissipation component 13 by the silk-screen printing, or, alternatively, the thermal phase-change material layer 12 is formed on the heating component 11 by the silk-screen printing.

In a normal condition, a thermal phase-change material is at a viscous phase and stored in a sealed pot at the temperature being under 27° C. Before using the thermal phase-change material, effective stir process must be required to ensure that the thermal phase-change material can be mixed with the solvent uniformly, such that the thermal phase-change material becomes to be in a viscous state. Thus, the thermal phase-change material in the viscous phase can be printed by a silk-screen printer to manufacture thermal phase-change material layer 12 with the thickness of 0.02-0.3 mm. During the manufacture of the thermal phase-change material layer 12, the thermal phase-change material layer 12 is formed by designating a corresponding opening region on the screen of the silk-screen printer according to the shape or area of the heating component 11 or the heat dissipation component 13, and adjusting the thickness of the screen.

The area of the thermal phase-change material layer 12 is equal to the area of the heating surface of the heating component 11 to ensure the fully contact on the contact face. In other words, no matter what the shapes of the heating surface of the heating component 11 is (a regular shape or irregular shape), the area of the thermal phase-change material layer 12 is equal to the area of the heating surface of the heating component 11, alternatively, the area of the thermal phase-change material layer 12 is slightly larger or smaller than the area of the heating surface of the heating component 11. In an embodiment, the area of the thermal phase-change material layer 12 is equal to the area of the heat absorbing surface of the heat dissipation component 13, or the area of the thermal phase-change material layer 12 is slightly larger or smaller than the area of the heat absorbing surface of the heat dissipation component 13.

It would be understood that the area of the thermal phase-change material layer 12 is determined according to specific design requirements. For example, when the thermal phase-change material layer 12 is applied for a mobile phone chip (heating component 11) on the front of the PCB circuit board, the area of the thermal phase-change material layer 12 is slightly smaller than the area of the mobile phone chip (heating component 11). When the thermal phase-change material layer 12 is applied for the corresponding heat region on the back of the PCB circuit board, the area of the thermal phase-change material layer 12 is slightly larger than the area of the corresponding heat region on the back of the PCB circuit board. In brief, the thermal phase-change material layer 12 is designed to ensure the effective thermal conduction of the heating component 11 and the heat dissipation component 13.

Step S103: pressing the heat dissipation component 13 and the heating component 11 to each other to thermally connect the thermal phase-change material layer 12 between the heating surface of the heating component 11 and the heat absorbing surface of the heat dissipation component 13.

After the pressing process, the space between the heat absorbing surface and the heating surface is less than or equal to 0.1 mm. Further, the thickness of the thermal phase-change material layer 12 in the mobile phone is less than or equal to 0.1 mm. In the embodiment, the thermal phase-change material layer 12 has low hardness and better compressibility. Then, by pressing the heat dissipation component 13 and the heating component 11 to each other, the thermal phase-change material layer 12 is thermally connected between the heating surface of the heating component 11 and the heat absorbing surface of the heat dissipation component 13, such that the thickness of the thermal phase-change material layer 12 is less than or equal to 0.1 mm after the heat dissipation component 13 and the heating component 11 are pressed to each other. In an embodiment, after the heating component 11 and the heat dissipation component 13 are pressed to each other, the thickness of the thermal phase-change material layer 12 is less than or equal to 0.08 mm. Further, the area of the thermal phase-change material layer 12 is larger than or equal to 15 mm×15 mm.

The thermal phase-change material layer 12 has a grid structure or polygon structure. Via the above specific structures, overflow conditions is reduced, and the thermal phase-change material layer 12 with larger area and less thickness is obtained. In another embodiment, the thermal phase-change material layer 12 is a block type or a large plane type. It would be understood that the structure of the thermal phase-change material layer 12 is designed in response to specific requirements to be of any shape.

The thermal phase-change material layer 12 has a phase-change temperature which is in the range of 40° C.-60° C. When the temperature of the heating component 11 reaches or exceeds the phase-change temperature, the thermal phase-change material layer 12 is changed to a melting phase from a solid phase and then fills the space between the heating component 11 and the heat dissipation component 13 to ensure the well contact between the thermal phase-change material layer 12, the heating component 11, and the heat dissipation component 13. Thus, the heat can be effectively conducted from the heating component 11 to the heat dissipation component 13 through the thermal phase-change material layer 12.

In the embodiment, the thickness of the thermal phase-change material layer 12 is configured to maintain the shape of the thermal phase-change material layer 12 at the melting phase to be the same as the shape at the solid phase through the surface adsobability and tension of the thermal phase-change material layer 12. That is, when the temperature of the heating component 11 reaches the phase-change temperature in the range 40° C.-70° C., the thermal phase-change material layer 12 is changed to the melting phase from the solid phase and then fills the space between the heating component 11 and the heat dissipation component 13. However, since the thermal phase-change material layer 12 has the grid structure, the polygon structure, or a shape with a larger area formed by the silk-screen printing, the shape of the thermal phase-change material layer 12 at the melting phase is maintained as the same shape at the solid phase through the surface adsobability and tension of the thermal phase-change material layer 12. When the temperature of the heating component 11 is lower than the phase-change temperature the thermal phase-change material layer 12 is automatically changed to the original shape.

As the above description, the mobile phone in the embodiment comprises a heating component having a heating surface, a heat dissipation component having a heat absorbing surface, and a thermal phase-change material layer. The thermal phase-change material layer is thermally connected between the heating surface of the heating component and the heat adsorbing surface of the heat dissipation component. The thermal phase-change material layer has a phase-change temperature. When the temperature of the heating component reaches or exceeds the phase-change temperature, the thermal phase-change material layer2 is changed to a melting phase from a solid phase and then fills the space between the heating component and the heat dissipation component to ensure the well contact between the thermal phase-change material layer, the heating component, and the heat dissipation component. Thus, the heat can be effectively conducted from the heating component to the heat dissipation component through the thermal phase-change material layer. Moreover, the phase-change material layer has lower cost, and the phase-change material layer can be manufactured by silk-screen printing. Further, the thickness of the thermal phase-change material layer 12 can be designed to be less than or equal to 0.1 mm, thus the space between the heat absorbing surface and the heating surface is less than or equal to 0.1 mm, hereby reducing the thickness of the mobile phone to realize ultra-thin design for the mobile phone.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A mobile phone, comprising:
a heating component having a heating surface;
a heat dissipation component having a heating absorbing surface; and
a thermal phase-change material layer, having a phase-change temperature, thermally connected between the heating surface of the heating component and the heat absorbing surface of the heat dissipation component,
when a temperature of the heating component reaches or exceeds the phase-change temperature, the thermal phase-change material layer is changed to a melting phase from a solid phase, and
the thermal phase-change material layer is manufactured by silk screen printing, and space between the heat absorbing surface and the heating surface is less than or equal 0.1 mm.

2. The mobile phone as claimed in claim 1, wherein a thickness of the thermal phase-change material layer is configured to maintain a shape of the thermal phase-change material layer at the melting phase to be the same as the shape of the thermal phase-change material layer at the solid phase through surface adsobability and tension of the thermal phase-change material layer.

3. The mobile phone as claimed in claim 1, wherein a thickness of the thermal phase-change material layer is less than or equal to 0.1 mm.

4. The mobile phone as claimed in claim 1, wherein an area of the thermal phase-change material layer is equal to an area of the heating surface of the heating component.

5. The mobile phone as claimed in claim 4, wherein an area of the thermal phase-change material layer is larger than or equal to 15 mm×15 mm.

6. The mobile phone as claimed in claim 1, wherein the heating component is a PCB component, a camera disposed inside the mobile phone, or a liquid crystal display screen disposed inside the mobile phone, and the heat dissipation component is a metallic sheathing

7. The mobile phone as claimed in claim 1, wherein the thermal phase-change material layer has a grid structure or polygon structure.

8. The mobile phone as claimed in claim 1, wherein the phase-change temperature is in a range of 40° C.-60° C.

9. A manufacturing method for a mobile phone, comprising:
providing a heating component having a heating surface and a heat dissipation component having a heat absorbing surface;
forming a thermal phase-change material layer on at least one of the heating component and the heat dissipation component through silk screen printing; and
pressing the heating component and the heat dissipation component to each other, so that the thermal phase-change material layer is thermally connected between the heating surface of the heating component and the heat absorbing surface of the heat dissipation component,
wherein the thermal phase-change material layer has a phase-change temperature,
wherein when a temperature of the heating component reaches or exceeds the phase-change temperature, the thermal phase-change material layer is changed to a melting phase from a solid phase, and
wherein after the heating component and the heat dissipation component are pressed to each other, space between the heat absorbing surface and the heating surface is less than or equal 0.1 mm.

10. The manufacturing method as claimed in claim 9, wherein a thickness of the thermal phase-change material layer is configured to maintain a shape of the thermal phase-change material layer at the melting phase to be the same as the shape of the thermal phase-change material layer at the solid phase through surface adsobability and tension of the thermal phase-change material layer.

11. The manufacturing method as claimed in claim 9, wherein a thickness of the thermal phase-change material layer is less than or equal to 0.1 mm.

12. The manufacturing method as claimed in claim 9, wherein an area of the thermal phase-change material layer is equal to an area of the heating surface of the heating component.

13. The manufacturing method as claimed in claim 12, wherein an area of the thermal phase-change material layer is larger than or equal to 15 mm×15 mm.

14. The manufacturing method as claimed in claim 9, wherein the heating component is a PCB component, a camera disposed inside the mobile phone, or a liquid crystal display screen disposed inside the mobile phone, and the heat dissipation component is a metallic sheathing

15. The manufacturing method as claimed in claim 9, wherein the thermal phase-change material layer has a grid structure or polygon structure.

16. The manufacturing method as claimed in claim 9, wherein the phase-change temperature is in a range of 40° C.-60° C.

17. A heat dissipation device, used in a mobile phone, comprising:
a thermal phase-change material layer, having a phase-change temperature, thermally connected between a heating surface of a heating component and the heat absorbing surface of the heat dissipation component,
when a temperature of the heating component reaches or exceeds the phase-change temperature, the thermal phase-change material layer is changed to a melting phase from a solid phase, and
the thermal phase-change material layer is manufactured by silk screen printing, and space between the heat absorbing surface and the heating surface is less than or equal 0.1 mm.
